(19) United States
(12) Patent Application Publication
(10) Pub. No.: US 2026/0213771 A1
(43) Pub. Date: Jul. 23, 2026

(54) METHOD AND APPARATUS FOR POWER-PERFORMANCE-AREA (PPA) ENHANCED RANDOM ERROR CORRECTION IN REED-SOLOMON (RS) CODES

(71) Applicant: Microchip Technology Incorporated, Chandler, AZ (US)

(72) Inventors: Diego Coelho, Calgary (CA); Peter Graumann, Calgary (CA); Chandra Chuda Varanasi, Broomfield, CO (US)

(21) Appl. No.: 19/387,565

(22) Filed: Nov. 12, 2025

Related U.S. Application Data
(60) Provisional application No. 63/747,766, filed on Jan. 21, 2025.

(51) Int. Cl. H03M 13/15

(52) U.S. Cl. CPC H03M 13/1515

(57) ABSTRACT

An apparatus and method are disclosed for error correction in Reed-Solomon (RS) code decoders. The apparatus may include a receiver configured to receive flow control unit (FLIT) blocks from a transmitter, wherein the FLIT blocks are encoded using Reed-Solomon codes with predefined burst error characteristics for transmission across one or more lanes. A FLIT block processing unit organizes and processes the FLIT blocks for decoding. An error locator polynomial computation module identifies error locations by generating an error locator polynomial based on the FLIT blocks, determining a symmetrical error pattern from the predefined burst error characteristics, defining a constrained polynomial root search space based on the symmetrical error pattern, and determining roots of the error locator polynomial within the constrained search space to identify error locations. An error magnitude computation module determines error magnitudes corresponding to the identified error locations using a direct computation method.

### CROSS-REFERENCE TO RELATED APPLICATION

The present application claims priority from U.S. Provisional Application No. 63/747,766 filed on Jan. 21, 2025, the contents of which are incorporated herein by reference in their entirety.

### TECHNICAL FIELD

The present disclosure relates generally to Reed-Solomon (RS) code processing, and more specifically to Power-Performance-Area (PPA) improved random error correction in RS codes.

### BACKGROUND

Reed-Solomon (RS) codes are widely used error-correcting codes (ECC) that provide protection against data corruption in high-reliability systems, including data storage, communication networks, and memory subsystems. Their ability to correct burst errors makes them valuable in environments prone to clustered error events, such as high-speed serial links and memory interfaces.

RS decoding typically involves three computational steps: (1) computing the Error Locator Polynomial (ELP) using the Berlekamp-Massey algorithm, (2) identifying the roots of the ELP via the Chien search algorithm, and (3) calculating error magnitudes using the Forney algorithm. These steps may involve sequential and iterative operations, polynomial evaluations, and field arithmetic, which can impact latency, area, and power consumption depending on implementation choices.

In many applications, such as PCI Express (PCIe) and DDR memory systems, error patterns may exhibit burst characteristics due to lane interleaving or device-level behavior. RS decoders are generally designed to address random error distributions, and may not be optimized for such structured error patterns.

Design trade-offs in RS decoder implementations can arise between latency, area, and power. For example, parallelization may improve throughput but increase resource usage, while power-efficient designs may reduce performance. These considerations are relevant in high-bandwidth systems where decoder scalability may be advantageous.

Accordingly, there is a need for error correction approaches that may address implementation considerations such as latency, area, and power, and that may be adaptable to structured error patterns encountered in modern data transmission and memory systems.

### SUMMARY

In high-speed data transmission and memory systems, error patterns often exhibit structured burst characteristics that conventional RS decoders may not efficiently address. These structured patterns can lead to increased latency, power consumption, and hardware complexity in traditional decoding implementations.

According to an aspect of one or more examples, there is provided an apparatus for error correction in a Reed-Solomon (RS) code decoder, that may include a receiver to receive flow control unit (FLIT) blocks from a transmitter, wherein the FLIT blocks are encoded using RS codes with predefined burst error characteristics for transmission across one or more lanes. A FLIT block processing unit may organize and process the FLIT blocks for decoding. An error locator polynomial computation module may identify error locations in the FLIT blocks by: generating an error locator polynomial based on the FLIT blocks; determining a symmetrical error pattern based on the predefined burst error characteristics, defining a constrained polynomial root search space based on said symmetrical error pattern, determining roots of the error locator polynomial within the constrained polynomial root search space; determining the error locations from the roots. An error magnitude computation module to determine error magnitudes, corresponding to the determined error locations, using a direct computation method.

According to an aspect of one or more examples, there is provided a method for error correction in a Reed-Solomon (RS) code decoder. The method may include receiving flow control unit (FLIT) blocks at a receiver from a transmitter, wherein the FLIT blocks are encoded using RS codes and further include predefined burst error characteristics. The method may also include generating an error locator polynomial based on the FLIT blocks. The method may further involve identifying error locations in the FLIT blocks by: determining a symmetrical error pattern based on the predefined burst error characteristics, defining a constrained polynomial root search space based on said symmetrical error pattern, determining roots of the error locator polynomial within the constrained polynomial root search space; determining the error locations from the roots. The method may also include calculating error magnitudes based on the determined error locations using a direct computation method.

According to an aspect of one or more examples, there is provided an apparatus for error correction in a Reed-Solomon (RS) code decoder. The apparatus may include a receiver to receive flow control unit (FLIT) blocks from a transmitter. The receiver may be configured to receive FLIT blocks, wherein the FLIT blocks are encoded using RS codes and further include predefined burst error characteristics, generate an error locator polynomial based on the FLIT blocks, identify error locations in the FLIT blocks by determining a symmetrical error pattern based on the predefined burst error characteristics, defining a constrained polynomial root search space based on said symmetrical error pattern, determining roots of the error locator polynomial within the constrained polynomial root search space, and determining error locations from the roots, and calculate error magnitudes based on the error locations using a direct computation method.

### BRIEF DESCRIPTION OF DRAWINGS

FIG. 1 shows a table of a Flow Control Unit (FLIT) block in a PCI Express (PCIe) x16 link according to one or more examples.

FIG. 2 shows a block diagram of an apparatus for error correction in a RS decoder according to one or more examples.

FIG. 3 shows a flow chart of a method for error correction according to one or more examples.

### DETAILED DESCRIPTION OF VARIOUS EXAMPLES

Reference will now be made in detail to the following various examples, which are illustrated in the accompanying drawings, wherein like reference numerals refer to like elements throughout. The following examples may be embodied in various forms without being limited to the examples set forth herein.

Reed-Solomon (RS) codes are a class of error-correcting codes (ECC) that are used to ensure data integrity across various domains, including automotive systems, computer applications, data storage solutions, and communication networks. RS codes are used in detecting and correcting burst errors, which makes them useful in high-reliability systems. Their ability to maintain data fidelity in noisy environments has established their use in both consumer and industrial applications.

Despite their widespread adoption, the implementation of RS code processing remains a challenging task. Intellectual Property (IP) cores designed for RS encoding and decoding are often characterized by high resource consumption, including significant area, power, and gate count. This high complexity arises primarily from the mathematical operations required for encoding at the transmitter side and decoding at the receiver side. The decoder component is generally more resource-intensive than the encoder, owing to the additional computational steps involved in error detection and correction.

The complexity of RS decoders stems from several specific operations, such as computing the Error Locator Polynomial (ELP) using the Berlekamp-Massey algorithm, finding the inverse of the ELP roots via the Chien search algorithm, and calculating error masks using the Forney algorithm. While the Berlekamp-Massey algorithm is iterative, the Chien search and Forney algorithms can be implemented in fully or partially parallel circuits, which reduce latency but come at the expense of significant hardware costs. These processes, particularly when handling a high number of errors, contribute to high resource usage and potential trade-offs between latency and hardware complexity. For instance, the Berlekamp-Massey algorithm involves O(n²) operations and is latency-intensive, while the parallelization of the Chien search and Forney algorithms impose additional computational costs.

As technology evolves, IP designers continuously seek advancements to reduce resource utilization, including reducing area, gate count, and power consumption, while simultaneously enhancing performance metrics such as throughput and latency. Achieving these goals often involves trade-offs among the different design parameters. For example, reducing latency might increase area and power, whereas decreasing power consumption might compromise throughput. Therefore, there exists a need for novel circuitry that reduces latency, area, and power simultaneously, without trade-offs among these metrics.

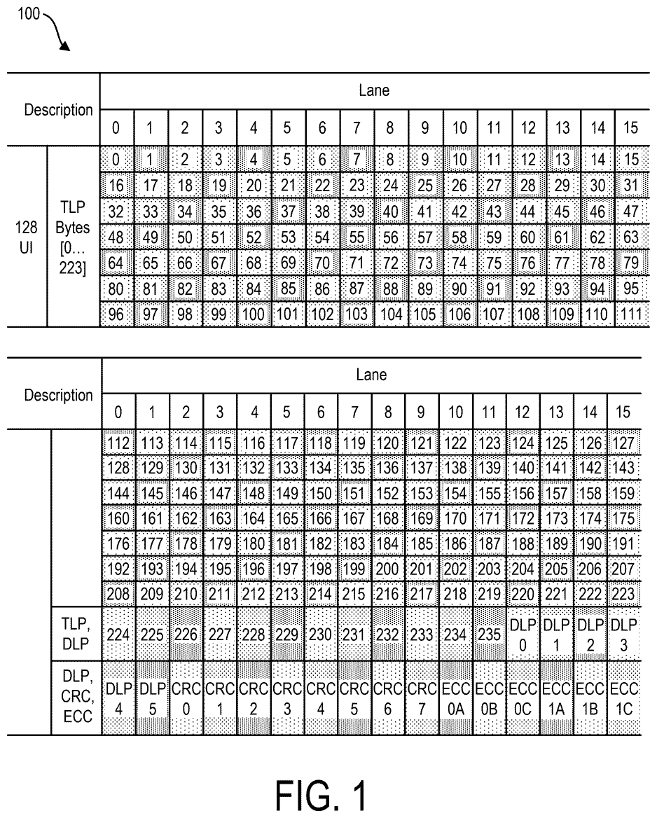

FIG. 1 shows a table of a Flow Control Unit (FLIT) block 100 in a PCI Express (PCIe) x16 link according to one or more examples. A FLIT block may be the smallest unit of data flow in certain communication systems, and adding error correction (ECC) or detection (CRC) may ensure reliable data transfer across noisy or unreliable channels. As shown in FIG. 1, the FLIT block 100 may include 256 bytes of data. This fixed size may ensure efficient handling of data across varying lane configurations (e.g., 1×, 2×, 4×, 8×, and 16×). The FLIT block 100 may be encoded with three interleaved (t1) Reed-Solomon (RS)-like codes enhanced for error correction capabilities in high-speed communication environments. As shown in the data layout, data components may include TLP (Transaction Layer Packet), DLP (Data Link Packet), CRC (Cyclic Redundancy Check), and ECC (Error Correction Code).

TLPs (e.g., bytes 0 through 235) may be the basic units of data communication in protocols like PCIe. TLPs may carry transaction data and include headers, payloads, and optional error detection or correction mechanisms. TLPs may include RS error-correcting codes or other forms of ECC to ensure reliable data transmission over noisy channels. DLPs (e.g., bytes DLP 0 through DLP 5) may be packets used at the data link layer to ensure reliable communication between directly connected devices. DLPs may handle acknowledgment, flow control, and error detection. DLPs may use CRC for error detection and may integrate RS codes for error correction, depending on the protocol. CRC (e.g., bytes CRC 0 through CRC 7) may be an error-detection mechanism that generates a checksum based on the transmitted data. If the checksum does not match the receiver's calculation, an error may be detected. CRC may complement RS codes by detecting errors not correctable or introduced by RS or by acting as a preliminary filter for corrupt data. Alternatively, CRC may be designed to be compatible with the mathematical structure of RS codes. This may involve aligning the properties of the CRC computation with field arithmetic and parameters of RS codes. ECC (e.g., bytes ECC OA through ECC 1C) may be a general term for any method of detecting and correcting errors in transmitted or stored data. RS codes may be a specific type of ECC. ECC, such as RS codes, may ensure data integrity by correcting errors caused by transmission noise or other issues. RS codes may be employed in FLIT blocks for their error correction capabilities. RS codes may be defined by specific parameters, denoted as (n, k, d), m, and the field over which they operate. (n, k, d) may be parameters of the RS code. n (codeword length) may be the total number of symbols in a codeword after encoding. In RS codes, n=2^{m}−1, where m is the number of bits per symbol. k (message length) may be the number of symbols in the original message before encoding. The RS encoder may add (n−k) parity symbols to the message. d (minimum distance) may be the minimum Hamming distance between any two valid codewords. For RS codes, d=n−k+1. t may represent error-correcting capability, and the code can correct up to

$$t = ⌊ \frac{d - 1}{2} ⌋ = ⌊ \frac{n - k}{2} ⌋$$

randomly located symbol errors. m (field size) may be the number of bits per symbol in the code, determining the size of the Galois Field (GF(2^{m})) used by the RS code. Each symbol in the RS code may correspond to an element in the Galois Field. For example, m=8 code operates over GF(2⁸), meaning each symbol is an 8-bit byte. n=2⁸−1=255, which is the maximum codeword length. RS codes may operate over finite fields (Galois Fields), denoted as GF(2^{m}). Aspects of the field may include a primitive polynomial and field elements. The primitive polynomial may define the structure of the Galois Field. Symbols used in the code may be elements of the field, such as 0, 1, α, α², . . . , α^{2m-2}, where α is a primitive element. The choice of field may impact the maximum codeword length and the range of possible symbol values.

A polynomial P(x) of degree d may be represented as: P(x)=a₀+a₁x+a₂x²+ . . . +a_{d}x^{d}, where the coefficients at are elements of the Galois Field GF(2^{m}). The roots of the polynomial may be sought among the elements of the Galois Field GF(2^{m}). For example, in GF(2³), there are 2³=8 elements: {0, 1, a, a², a³, . . . , a⁶}, where a is a primitive element of the field. To find the roots, each field element β may be substituted into P(x): P(β)=a₀+a₁β+a₂β²+ . . . +a_{d}β^{d}. If P(β)=0, then β is a root of the polynomial. When the degree of the polynomial or the size of the field is large, methods like Chien Search can be used to speed up the root-finding process. Each root βᵢ of the error locator polynomial may correspond to the position of an error in the received codeword. The error position in the received codeword may be identified as: Error Position=n−log_{α}(βᵢ), where a is the primitive element of the Galois Field, and n is the length of the codeword. To correct the errors, correction masks derived from the Forney algorithm may be XORed with the data in the received codeword at the locations identified by Chien search. The resulting RS block may pass a subsequent syndrome check if the error correction is successful. In scenarios where error events outside the RS (e.g., radiation-induced computational errors) occur, syndrome checks may be retried as part of data integrity verification. For protocols like PCIe, which utilize multiple codes, correctness may be cross-verified. For example, PCIe may employ three t1 codes and a CRC (or t4 RS code as used in some implementations). Error correction using one code may be verified by checking the syndromes of the others. Specifically, the syndromes of all the codes in the FLIT (Flow Control Unit) may be checked. If any of the syndrome values (t1s or t4) are non-zero, the decoder may signal a decode failure.

Referring back to FIG. 1, the FLIT block 100 may employ a CRC scheme based on RS codes. The CRC may be defined with the following parameters: n=250 (codeword length), k=242 (message length), d=8 (minimum distance). This RS-like encoding scheme may enable efficient detection and correction of burst errors, which are common in high-speed PCIe links.

A decoder may address constrained error scenarios, including four errors in one burst (4, 1), where errors occur at fixed intervals (e.g., {0, 16, 32, 48} in Lane 0), and four errors in two bursts (4, 2), where errors are distributed across two bursts at specified offsets (e.g., {0, 16, 58, 74} in Lanes 0 and 10). The decoder may leverage these predictable error distributions to reduce computational complexity while maintaining high reliability. The decoder may achieve this by focusing resources on realistic error scenarios rather than general-case decoding, which is often computationally expensive. The decoder may support flexible lane configurations. Data may be transmitted across PCIe 1×, 2×, 4×, 8×, or 16× lanes. Each lane may be allocated a subset of the 256-byte FLIT block for parallel transmission, increasing throughput in high-bandwidth applications.

For example, for data transmitted across PCIe x1 (e.g., Lane 0), the decoder may operate on an RS code with the following parameters: n=250 (codeword length), k=242 (message length), d=9 (minimum distance), m=8 (8-bit symbols, operating in GF(2⁸)), and field x⁸+x⁵+x³+x¹+1. This RS configuration may enable correction of errors encountered in high-speed PCIe Gen 7 links.

The decoder may focus on correcting constrained error patterns, including four errors in one burst (4, 1) and four errors distributed across two bursts (4, 2). Assuming a burst of length four, errors may occur in a single burst at positions X, X+1, X+2, X+3. Assuming two bursts of length two, errors may occur in two bursts at positions X, X+1 and Y, Y+1. These predictable patterns may allow the decoder to improve error correction logic, focusing on realistic scenarios encountered in practice.

The decoder may compute the Error Locator Polynomial (ELP), σ(x), to identify error locations: σ(x)=1+σ₁x+σ₂x²+σ₃x³+σ₄x⁴. By leveraging symmetries in error distribution, the decoder may simplify the process of finding the roots of (x). For a burst of length four, the roots may be determined by using the relation:

$${α}^{6} {a}^{4} = \frac{1}{{σ}_{4}} .$$

For two bursts of length two, the roots may be calculated using the quadratic equation:

$${a}^{2} + \frac{{σ}_{3}}{{( 1 + α )}^{2} {σ}_{4}} a + \frac{{σ}_{2}}{( 1 + α ) ( 1 + {α}^{3} ) {σ}_{4}} = 0 ( 7 ) .$$

The decoder may replace the Forney algorithm with a direct computation method for error magnitudes. For a burst of length four,

$$β = \frac{1}{a} , \frac{k}{a} , \frac{{k}^{2}}{a} , \frac{{k}^{3}}{a} .$$

For two bursts of length two,

$$β = \frac{1}{a} , \frac{k}{a} and \frac{1}{b} , \frac{k}{b} .$$

This direct approach may eliminate the iterative multiplications and inversions typically used by the Forney algorithm, resulting in reductions in latency and resource usage. The decoder may simplify root finding and error magnitude calculations by using field symmetries, reduce or eliminate iterative computations thereby reducing decoding latency, and minimize the number of multiplications and hardware logic for error correction.

As another example, for data transmitted across PCIe x16 (e.g., Lanes 0 through 15), the decoder may utilize a RS code with the following parameters: n=250 (codeword length), k=242 (message length), d=8 (minimum distance), m=8 (8-bit symbols, operating in GF(2⁸)), and field x⁸+x⁵+x³+x¹+1. These parameters may be tailored for error correction in high-speed PCIe Gen 7 links operating across 16 lanes.

The decoder may focus on correcting constrained error patterns arising from lane interleaving, including four errors in one burst (4, 1) and four errors distributed across two bursts (4, 2). Assuming a burst of length four, errors may occur at fixed positions spaced by 16 lanes (e.g., positions X, X+16, X+32, X+48). Assuming two bursts of length two, errors may occur at X, X+16 and Y, Y+16. These predictable error patterns may enable the decoder to improve its logic, avoiding computations for unrealistic error scenarios.

The Error Locator Polynomial (ELP), σ(x), may identify the locations of errors: σ(x)=1+σ₁x+σ₂x²+σ₃x³+σ₄x⁴. The decoder may exploit symmetries in the error distribution to simplify root-finding operations. For a burst of length four, the roots may be calculated by using the relation:

$${α}^{96} {a}^{4} = \frac{1}{{σ}_{4}} .$$

For two bursts of length two, the roots may be calculated by using the quadratic equation:

$${a}^{2} + \frac{{σ}_{3}}{{( 1 + {α}^{16} )}^{2} {σ}_{4}} a + \frac{{σ}_{2}}{( 1 + {α}^{16} ) ( 1 + {α}^{48} ) {σ}_{4}} = 0 ( 7 ) .$$

The Forney algorithm, traditionally used to compute error magnitudes, may be replaced with a direct computation approach. For a burst of length four,

$$β = \frac{1}{a} , \frac{{k}^{16}}{a} , \frac{{k}^{32}}{a} , \frac{{k}^{48}}{a} .$$

For two bursts of length two,

$$β = \frac{1}{a} , \frac{{k}^{16}}{a} and \frac{1}{b} , \frac{{k}^{16}}{b} .$$

This direct computation may eliminate iterative multiplications and inversions, reducing latency and resource usage. The decoder may support high-lane-count configurations, such as PCIe x16, with improved decoding logic, simplify root-finding and error magnitude calculations by exploiting symmetries, avoid iterative algorithms thereby reducing decoding latency and hardware overhead, and correct constrained error patterns commonly encountered in PCIe links, ensuring robust data transmission.

As yet another example, for CXL (Compute Express Link) DDR5 systems, the decoder may utilize a RS code with the following parameters: n=88 (codeword length), k=72 (message length), d=16 (minimum distance), m=8 (8-bit symbols, operating in GF(2⁸), and field x8+x4+x3+x2+1. These parameters may be used for error correction in DDR5 memory systems, where burst errors are common due to device failures.

The decoder may target specific constrained error patterns, including eight errors in one burst (8, 1), and four errors distributed across two bursts (4, 2). Assuming a burst of length eight, errors may occur consecutively at positions X, X+1, X+2, X+3, X+4, X+5, X+6, X+7. The predictable nature of these error patterns may enable the decoder to streamline its operations, focusing only on realistic and high-likelihood scenarios. This approach may be particularly relevant in applications where device-level failures lead to sequential root patterns, such as DDR device failures or other memory and storage systems. For example, in a CXL error correction application, sequential error correction may be directly utilized to address these constrained patterns effectively. More broadly, this approach may be applicable to any scenarios involving sequential error cases, enhancing the efficiency and reliability of error correction in diverse systems prone to such failures.

The Error Locator Polynomial (ELP), σ(x), may be defined to identify the locations of errors:

$$σ ( x ) = 1 + {\sum }_{i = 1}^{8} {σ}_{i} {x}_{i} .$$

By leveraging the symmetry in error distributions, the decoder may simplify the process of finding the roots of the ELP. For a burst of length eight, the roots may be calculated by using the relation:

$${α}^{28} {a}^{8} = \frac{1}{{σ}_{8}} .$$

This approach may reduce or eliminate the need for computationally expensive iterative root-finding algorithms.

The decoder may replace the traditional Forney algorithm with a direct computation method for error magnitudes. For a burst of length eight,

$$β = \frac{1}{a} , \frac{k}{a} , \frac{{k}^{2}}{a} , \frac{{k}^{3}}{a} , \frac{{k}^{4}}{a} , \frac{{k}^{5}}{a} , \frac{{k}^{6}}{a} , \frac{{k}^{7}}{a} .$$

This direct computation may reduce the hardware complexity and latency associated with decoding operations. The decoder may simplify root-finding and error magnitude computations by exploiting field symmetries, avoid iterative operations thereby reducing decoding latency and hardware resource requirements, handle burst errors caused by device failures thereby ensuring robust error correction for DDR5 memory systems, and adapt to various error correction scenarios with little to no changes to the decoding architecture.

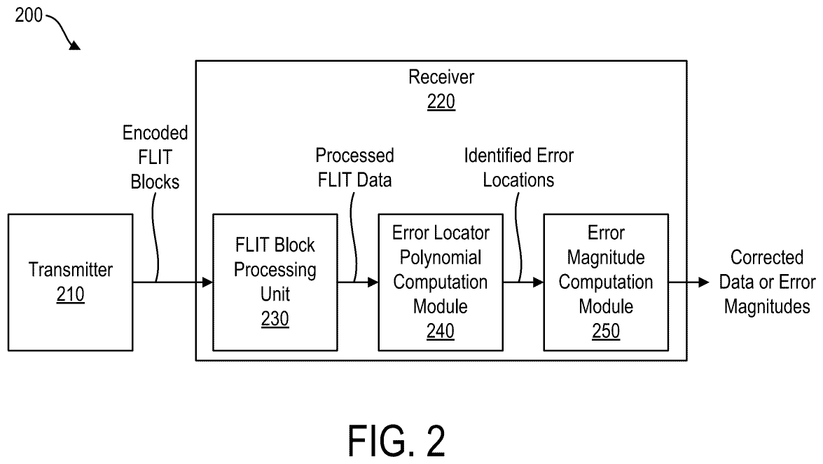

FIG. 2 shows a block diagram of an apparatus 200 for error correction in a RS decoder according to one or more examples. As shown in FIG. 2, the apparatus 200 may include several functional units, each designed to facilitate the encoding, transmission, reception, and decoding of data for error correction purposes. The flow of data between these units may be depicted with arrows to indicate the sequential and logical operations performed.

The transmitter 210 may encode data into FLIT blocks using RS codes. These RS codes may be parameterized by predefined configurations such as codeword length (n), message length (k), and minimum distance (d). The encoding process may generate FLIT blocks that are resistant to transmission errors by adding redundancy for error correction. This may ensure robust data integrity during transmission across communication channels.

The receiver 220 may be responsible for receiving the FLIT blocks transmitted over one or more communication lanes. These lanes may be physical or logical channels, such as high-speed serial links or network paths. The receiver 220 may ensure that the transmitted FLIT blocks are captured correctly and forwarded to the next stage for further processing. The receiver 220 may include the FLIT block processing unit 230, the error locator polynomial computation module 240, and the error magnitude computation module 250.

The FLIT block processing unit 230 may organize and process the received FLIT blocks to prepare them for decoding. The FLIT block processing unit 230 may align the data structure, extract relevant components, and prepare the symbols for error correction. By reassembling and validating the received blocks, the FLIT block processing unit 230 may ensure that the data is ready for accurate error detection and correction.

The error locator polynomial computation module 240 may identify the location of errors in the received FLIT blocks. The error locator polynomial computation module 240 may compute the error locator polynomial using mathematical operations defined by the RS algorithm. This may involve leveraging the syndrome values derived from the received codeword to pinpoint erroneous symbols. The error locator polynomial computation module 240 may exploit symmetries in the error distribution to simplify the process of finding the roots of the error locator polynomial. The error locator polynomial computation module 240 may identify error locations based on the roots of the error locator polynomial. The error locator polynomial computation module 240 may include a root-finding module to identify error locations in the received data, or alternatively, the error locator polynomial computation module 240 may provide the computed error locator polynomial as input to a separate root-finding module, which determines the roots of the error locator polynomial to identify the error locations.

The error magnitude computation module 250 may calculate the magnitudes of the identified errors. Using a direct computation method, the error magnitude computation module 250 may determine the precise corrections to restore the original data. The error magnitude computation module 250 may work in conjunction with the error locator polynomial computation module 240 to apply corrections to the corrupted symbols.

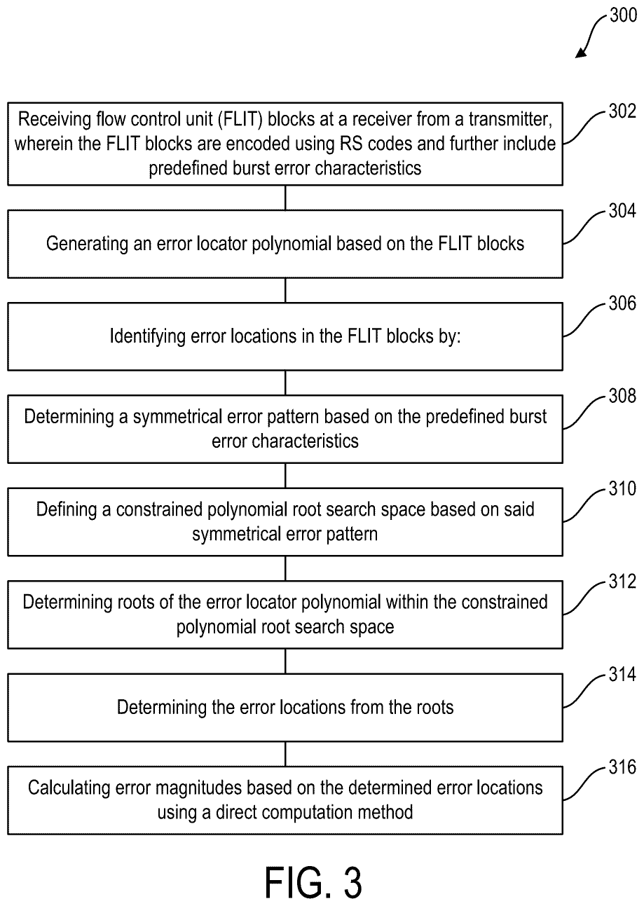

FIG. 3 shows a flow chart of method 300 for error correction according to one or more examples. In an aspect of one or more examples, the method illustrated in FIG. 3 may be executed within a PCI Express (PCIe) Gen 7 system configured for high-throughput data transmission across a 16-lane link. In this system, data is transmitted in flow control unit (FLIT) blocks, each comprising 256 bytes and encoded using Reed-Solomon (RS) codes. Due to lane interleaving and device-level behavior, these FLIT blocks exhibit constrained and predictable burst error patterns, such as four errors occurring at fixed intervals across specific lanes. These patterns are not random but arise from known physical and architectural behaviors in PCIe Gen 7 systems.

A receiver (e.g., the receiver 220 of FIG. 2), integrated into a memory controller or SerDes PHY, may implement the method of FIG. 3 to detect and correct such errors in real time, thereby preserving data integrity with reduced latency and hardware overhead.

For example, consider a FLIT block transmitted across a PCIe x16 link, encoded using an RS code with parameters n=250, k=242, and d=8. The block may include a burst error pattern such as four errors occurring at positions spaced by 16 bytes (e.g., positions 0, 16, 32, and 48). The receiver may apply the method of FIG. 3 to correct these errors using symmetry-aware decoding logic.

At step 302, the method 300 may involve receiving flow control unit (FLIT) blocks at a receiver from a transmitter, wherein the FLIT blocks are encoded using RS codes and further include predefined burst error characteristics. This step may be performed by the receiver 220, which includes a FLIT block processing unit 230. The receiver captures FLIT blocks transmitted over one or more PCIe lanes. Each FLIT block is encoded using RS codes with predefined parameters and includes structured burst error characteristics, such as single or dual bursts occurring at known intervals.

At step 304, the method 300 may involve generating an error locator polynomial based on the FLIT blocks. This step may be performed by the error locator polynomial computation module 240. The module computes the error locator polynomial (ELP), denoted σ(x), using syndrome values derived from the received FLIT block. The polynomial may be computed using a modified Berlekamp-Massey algorithm or other suitable techniques adapted for constrained error patterns. For example, the receiver 220 computes σ(x)=1+σ₁x+σ₂x²+σ₃x³+σ₄x⁴, based on syndrome values extracted from the received FLIT block.

At step 306, the method 300 may involve identifying error locations in the FLIT blocks by performing one or more subsequent steps. This step may initiate a multi-part subroutine to determine the locations of errors in the received data.

At step 308, the method 300 may involve determining a symmetrical error pattern based on the predefined burst error characteristics. The error locator polynomial computation module 240 may analyze the burst error characteristics and select a symmetrical error pattern. A symmetrical error pattern refers to a structured arrangement of error positions within a codeword or data block that exhibits predictable spacing or mirroring properties. This includes: (i) fixed interval spacing (e.g., errors at positions 0, 16, 32, 48), (ii) mirrored bursts across transmission lanes (e.g., errors in Lane 0 and Lane 10 at similar offsets), and (iii) field-theoretic symmetry in the Galois Field, where error positions correspond to powers of a primitive element spaced by a constant factor. These symmetrical patterns are used to constrain the polynomial root search space and simplify error location identification by leveraging predictable error distributions.

At step 310, the method 300 may involve defining a constrained polynomial root search space based on said symmetrical error pattern. Using the identified symmetry, the module constrains the root search space to a subset of the Galois Field GF(2⁸), thereby reducing computational complexity. Candidate roots are selected based on the expected burst pattern. For example, the receiver may limit the root search to positions spaced by 16 in GF(2⁸), such as α⁰, α¹⁶, α³², and α⁴⁸, where α is the primitive element.

At step 312, the method 300 may involve determining roots of the error locator polynomial within the constrained polynomial root search space. The error locator polynomial computation module 240 may perform root finding within the constrained space using direct evaluation. For example, the receiver may determine that α₁₆, α₃₂, α₄₈, and α₆₄ are roots of σ(x), indicating errors at positions 16, 32, 48, and 64 in the FLIT block.

At step 314, the method 300 may involve determining the error locations from the roots. The error locator polynomial computation module 240 may leverage symmetries in error distribution to simplify the process of finding the roots of σ(x). For a burst of length four, the roots may be determined by using the relation: α⁶·α⁴=1/σ₄. For two bursts of length two, the roots may be calculated using the quadratic equation: a²+(σ₃/((1+α)²·σ₄))·a+(σ₂/((1+α)(1+α³)·σ₄))=0.

At step 316, the method 300 may involve calculating error magnitudes based on the determined error locations using a direct computation method. This step may be performed by the error magnitude computation module 250. The error magnitude computation module 250 may apply a direct computation method tailored to the burst pattern. For a burst of length four, β={1/a, k/a, k2/a, k3/a}. For two bursts of length two, β={1/a, k/a} and {1/b, k/b}. This method eliminates the need for iterative multiplications and inversions typically required by the Forney algorithm.

By executing the method of FIG. 3, the receiver in the PCIe Gen 7 system may successfully identify and correct burst errors in the received FLIT block. The use of symmetrical error patterns and constrained polynomial root search spaces may enable efficient decoding with reduced latency and hardware complexity. The method 300 may be implemented in hardware logic with limited area and power overhead, eliminating or reducing the need for traditional Chien and Forney blocks and supporting real-time error correction in high-bandwidth communication systems.

Various examples have been disclosed herein, in connection with the above description and the drawings. It will be understood that it would be unduly repetitious to literally describe and illustrate every combination and sub-combination of these examples. Accordingly, all examples can be combined in any way or combination, and the present specification, including the drawings, shall be construed to constitute a complete written description of all combinations and sub-combinations of the examples described herein, and of the manner and process of making and using them, and shall support claims to any such combination or sub-combination.

It will be appreciated by persons skilled in the art that the examples described herein are not limited to what has been particularly shown and described herein above. In addition, unless mention was made above to the contrary, it should be noted that all of the accompanying drawings are not to scale. A variety of modifications and variations are possible in light of the above teachings.

What is claimed is:

1. An apparatus for error correction in a Reed-Solomon (RS) code decoder, comprising:
a receiver to receive flow control unit (FLIT) blocks from a transmitter, wherein the FLIT blocks are encoded using RS codes with predefined burst error characteristics for transmission across one or more lanes;
a FLIT block processing unit to organize and process the FLIT blocks for decoding;
an error locator polynomial computation module to identify error locations in the FLIT blocks by:
generating an error locator polynomial based on the FLIT blocks;
determining a symmetrical error pattern based on the predefined burst error characteristics,
defining a constrained polynomial root search space based on said symmetrical error pattern,
determining roots of the error locator polynomial within the constrained polynomial root search space;
determining the error locations from the roots; and
an error magnitude computation module to determine error magnitudes, corresponding to the determined error locations, using a direct computation method.

2. The apparatus of claim 1, wherein the predefined burst error characteristics include data indicative of one burst error or two burst errors in the FLIT blocks.

3. The apparatus of claim 1, wherein the error locations are defined by a starting position and a burst length.

4. The apparatus of claim 1, wherein the error locator polynomial computation module is configured to apply the symmetrical error pattern by using a mathematical constraint relationship to limit possible root values associated with the roots, wherein the error locator polynomial computation module is to simplify error location identification by using predictable error patterns.

5. The apparatus of claim 1, wherein the FLIT blocks are transmitted via a communication channel.

6. The apparatus of claim 5, wherein the communication channel comprises a PCIe interface.

7. The apparatus of claim 5, wherein the communication channel comprises a DDR memory interface.

8. The apparatus of claim 1, wherein the RS decoder is integrated into a memory controller for correcting burst errors caused by device failures.

9. The apparatus of claim 1, wherein determining the error magnitudes comprises determining corrections to the error locations that restore the FLIT blocks with original data.

10. The apparatus of claim 1, wherein generating the error locator polynomial comprises determining polynomial coefficients based on the burst error characteristics.

11. A method for error correction in a Reed-Solomon (RS) code decoder, comprising:
receiving flow control unit (FLIT) blocks at a receiver from a transmitter, wherein the FLIT blocks are encoded using RS codes and further include predefined burst error characteristics;
generating an error locator polynomial based on the FLIT blocks;
identifying error locations in the FLIT blocks by:
determining a symmetrical error pattern based on the predefined burst error characteristics,
defining a constrained polynomial root search space based on said symmetrical error pattern,
determining roots of the error locator polynomial within the constrained polynomial root search space;
determining the error locations from the roots; and
calculating error magnitudes based on the error positions using a direct computation method.

12. The method of claim 11, wherein the predefined burst error characteristics include data indicative of one burst error or two burst errors in the FLIT blocks.

13. The method of claim 11, wherein the error locations are defined by a starting position and a burst length.

14. The method of claim 11, comprising applying the symmetrical error pattern comprises using a mathematical constraint relationship to limit possible root values associated with the roots.

15. The method of claim 11, wherein the FLIT blocks are transmitted via a communication channel.

16. The method of claim 15, wherein the communication channel comprises a PCIe interface.

17. The method of claim 15, wherein the communication channel comprises a DDR memory interface.

18. An apparatus for error correction in a Reed-Solomon (RS) code decoder, comprising:
a receiver to receive FLIT blocks from a transmitter, the receiver configured to:
receive FLIT blocks, wherein the FLIT blocks are encoded using RS codes and further include predefined burst error characteristics;
generate an error locator polynomial based on the FLIT blocks;
identify error locations in the FLIT blocks by:
determining a symmetrical error pattern based on the predefined burst error characteristics,
defining a constrained polynomial root search space based on said symmetrical error pattern,
determining roots of the error locator polynomial within the constrained polynomial root search space;
determining error locations from the roots; and
calculate error magnitudes based on the error positions using a direct computation method.

19. The apparatus of claim 18, wherein the predefined burst error characteristics include data indicative of one burst error or two burst errors in the FLIT blocks.

20. The apparatus of claim 18, wherein the error positions are defined by a starting position and a burst length.
